(19) United States
(12) Patent Application Publication
(10) Pub. No.: US 2001/0055398 A1
(43) Pub. Date: Dec. 27, 2001

(54) Real time audio spatialisation system with high level control

(76) Inventors: Francois Pachet, Paris (FR); Olivier Delerue, Paris (FR)

Correspondence Address: William S. Frommer, Esq., FROMMER LAWRENCE & HAUG LLP, 745 Fifth Avenue, New York, NY, 10151, US

(21) Appl. No.: 09/808,895

(22) Filed: Mar. 15, 2001

(30) Foreign Application Priority Data
Mar. 17, 2000 (EP) 00 400 749.8
Feb. 15, 2001 (EP) 01 400 401.4

(51) Int. Cl. H04B 3/00; H03G 5/00

(52) U.S. Cl. 381/80; 381/98

(57) ABSTRACT

The invention relates to a system and method for controlling an audio spatialisation in real time, comprising:

input means (50) for accessing an audio stream composed of a plurality of audio sources associated to audio tracks,

constraint means (3) for receiving and processing constraints expressing rules for a spatialisation of the audio stream, and

interface means (2) for entering spatialising commands to the constraint means.

The interface means (2) presents at least one user input for effecting a grouped spatialisation command, the command acting on a specified group of audio sources, and the constraint means (3) is programmed to process the group of audio sources as a unitary object for the application of the constraint variables.

The group of audio sources typically reflects an internal coherence with respect to the rules for spatialisation.

The interface means (2) can be adapted to display:

at least one group icon (H) representing a grouped spatialisation command, the icon being positioned according to a topology reflecting a spatialisation and being displaceable by a user, and

links between the icons expressing constraints to be applied between the group icons.

### DESCRIPTION

The present invention relates to a system in which a listener or user can control the spatialisation of sound sources, i.e. sound tracks, in real time, so as to produce a spatialised mixing or so-called “multi-channel sound”. The spatialised mixing must satisfy a set of constraints which is defined a priori and stored in an audio file. Such a file is also called an audio support or audio carrier. The invention further relates to a method of spatialisation implemented through such a system.

Music spatialisation has long been the subject of intensive study in computer music research. However, most of the work so far has concentrated in building software to simulate acoustic environments for existing sound signals. These techniques typically exploit differences of amplitude in sound is channels, delays between sound channels to account for inter-aural distances, and sound filtering techniques such as reverberation to recreate impressions of distance. Such a technology is disclosed e.g. in an article published by Jot J. -M., Warusfel O. under the title “A Real-Time Spatial Sound Processor for Music and Virtual Reality Applications”, Proceedings of ICMC, 1995. These spatialisation techniques are mostly used for building virtual reality environments, as disclosed e.g. in articles published by Eckel G. under the title “Exploring Musical Space by Means of Virtual Architecture”, Proceedings of the 8^{th} International Symposium on Electronic Art, School of the Art Institute of Chicago, 1997, or by Lea R., Matsuda K., Miyashita K. under the title “Java for 3D and worlds”, New Riders Publishing, 1996.

By comparison, the present invention builds on a constraint technology, which relates sound sources to one another.

The invention is compatible with the so-called “MusicSpace” construction, which aims at providing a higher-level user control on music spatialisation, i.e. the position of sound sources and the position of the listener's representation on a display, compared to the level attained by the prior art.

The invention is based on the introduction of a constraint system in a graphical user interface connected to a spatialiser and representing the sound sources. A constraint system allows to express various sorts of limits on configuration of sound sources. For instance, when the user commands the displacement of one sound source through the interface or via a control language, the constraint system is activated and ensures that the constraints are not violated by the command. A first Midi version of the MusicSpace has already been designed and proved very successful. A description of such a constraint-based system can be found in European patent application EP-A-0 961 523 by the present applicant, and whose contents are hereby incorporated by reference.

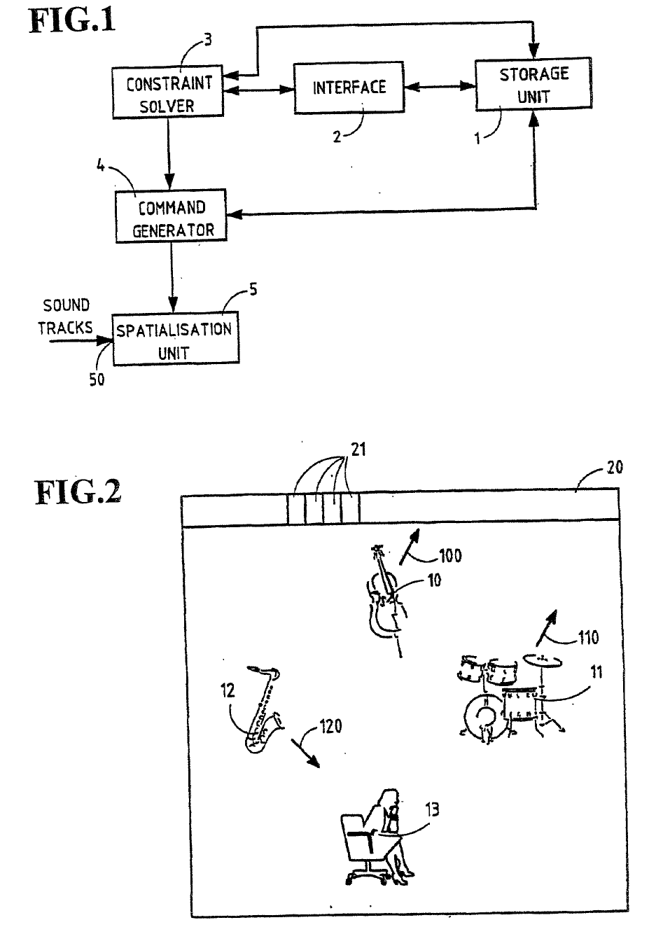

The constraint based music spatialisation concept according to EP-A-0 961 523 shall be briefly recalled with reference to FIG. 1.

A storage unit 1 is provided for storing data representative of one or several sound sources 10-12 (e.g. individual musical instruments) as well as a listener 13 of these sound sources. This data effectively comprises information on respective positions of sound sources and the listener. The user has access to a graphics interface 2 through which he/she can select a symbol representing the listener or a sound source and thereby change the position data, e.g. by dragging a selected symbol to a different part of the screen. An individual symbol is thereby associated to a variable. For instance, the user can use the interface to move one or several depicted instruments at different distances or at different relative positions to command a new spatialisation (i.e. overall s spatial distribution of the listener and sound sources).

Once a new spatialisation has thereby been entered, a constraint solving system 3 comes into effect for attempting to make the command compatible with predetermined constraints. This involves adjusting the positions of sound sources and/or the listener other than the sound source(s) selected by command to accommodate for the constraints. In other words, if a group of sound individual sources is displaced by the user through the interface 2 (causing what is a termed a “perturbation”), the constraint solving system will shift the positions of one or more other sound sources so that the overall spatial distributions still remains within the constraints imposed.

FIG. 2 shows a typical graphics display 20 as it appears on the interface 2, in which sound sources are symbolised by musical instruments 10-12 placed in the vicinity of an icon symbolising the listener 13. The interface 2 Per comprises an input device (not shown), such as a mouse, through which the relative positions of the graphical objects can be changed and entered. All spatialisations entered this way are sent to the constraint solver 3 for analysis.

In this context, the constraints can be that: the respective distances between two given sound sources and the listener should always remain in the same ratio, the product of the respective distances between each sound source and the listener should always remain constant, the sound source should not cross a predetermined radial limit with respect to the listener, or a given sound source should not cross a predetermined angular limit with respect to the listener. These constraints are processed by algorithms in terms of inequality relationships.

If the constraint solving system 3 cannot find a way of readjusting the other sound sources to accommodate for the newly entered spatialisation, it sends the user a message that the selected spatialisation cannot be implemented, and the sound sources are all returned to their initial position.

The constraint solving system implements a constraint propagation algorithm which generally consists in propagating recursively the perturbation caused by the displacement of a sound source or listener to the other sound sources with which it is linked through constraints. The particular algorithm used in accordance with EP-A-0 961 523 has the following additional characteristics:

the inequality constraints associated with the constraints are merely checked. If an equality constraint is not satisfied, the algorithm is ended and the search for a spatialisation is abandoned;

for each functional constraint, in response to the perturbation of one of the variables involved by the constraint, arbitrary new values are given to the other variables. Thus, a single arbitrary solution is determined for a given constraint (unlike the general constraint propagation algorithms which search for all solutions for a given constraint); and

when a given variable has been perturbed, i.e. when its value has been changed by the user or an arbitrary new value has been given thereto by the algorithm, this variable is not perturbed again dung the progress of the algorithm. For instance, if a variable is involved in two different constraints and an arbitrary new value is given to this variable in relation with the first one of the constraints, the algorithm cannot change the arbitrary new value already assigned to the variable in relation with the second of the constraints. If the arbitrary new value that the algorithm proposes to give to the variable in relation with the second constraint is different from the arbitrary new value selected for satisfying the first constraint, then the algorithm is ended with the entered spatialisation command refused.

For further information on prior art spatialisation, reference can also be made to the article by Pachet, F. and Delerue, O. under the title <<( MusicSpace: a Constraint-Based Control System for Music spatialisation >>, Proceedings of the 1999 International Computer Music Conference, which introduces a means for controlling the spatialisation of sound sources based on the constraint paradigm (i.e. a set of contextual examples under which the constraints apply).

However, the all the known examples of constraint technology such as disclosed in the above sources are focused on the so-called “Midi format”, i.e. a midi output or midi based communication with mixing devices and is thus limited in their scope of applicability. Indeed, provision of separately controlling each sound source—within the constraints—requires a large number of tracks to be managed, each source having to be allocated a separate track. This makes the prior art spatialisation systems difficult to implement on home audio systems that use classical recording media such as compact disks (CDs), digital versatile disks (DVDs), mini disks, etc., especially when the number of sound sources is relatively large.

Also, letting users change spatialisation arbitrarily induces the risk that the original coherence of the configuration of sound sources is no longer preserved, even if the constraints are strictly satisfied. Indeed, the Applicant has found that a reconfiguration of sound sources by individual adjustment often gives too many possibilities to the user, who does not necessarily have the expertise to use them to his or her advantage and may end with unsatisfying spatialisations.

Moreover, the implementation of constraints under these conditions can lead to frequent refusals to accept spatialisation commands, which may ultimately discourage the user from using the system.

In view of the foregoing problems, the invention proposes a spatialisation system and method which is easier to exploit both from the point of view of the user and the sound provider, better able to ensure that chosen spatialisations remain “aurally correct” and more amenable to standard recording techniques used in home audio systems.

The invention can be used to produce a fill audio system handling full-fledged multi-track audio files without the limitations of MDI based equipment.

It can be implemented with the so-called 3D sound buffer technology as a means for conferring a realistic impression of localization of sound sources. This technology is now mature enough to produce a fine-grained spatialisation on a set of audio sound sources in real time. However, it has up to now suffered serious limitations in the way it is used. Firstly, composers and sound engineers have great difficulty in mastering this technology to produce 3D sound pieces, because the corresponding control levels are at a too low level of software and intricate. As a consequence, the potential of this technology has not been fully exploited. In particular, listeners are still considered as passive receivers, and do not have any active control on the spatialisation of the pieces they listen to.

In view of the above, an object of the present invention is to introduce a concept of dynamic audio mixing, as well as a design of the system therefor, i.e. an implementation system such as “MusicSpace” referred to above, which solves the technical issues concerning the implementation of the audio extension.

The dynamic mixing addresses the following problems:

1) providing composers and sound engineers with a powerful paradigm to compose music pieces easily in space and time; and

2) at the same time granting listeners some degree of control on the spatialisation of the music they listen to.

Dynamic mixing fits naturally with the trend in new music standardization processes such as Mpeg4 and Mpeg7: dynamic mixing constraints are natural metadata. Additionally, the idea of reconstructing a musical piece “on-the-fly” conforms to the notion of scene description of Mpeg 4. Current work focuses on the design of a fully Mpeg7 compatible system.

To the above-mentioned end, there is provided a system for controlling an audio spatialisation in real time, comprising:

input means (50) for accessing an audio stream composed of a plurality of audio sources associated to audio tracks,

constraint means (3) for receiving and processing constraints expressing rules for a spatialisation of the audio stream, and

interface means (2) for entering spatialising commands to the constraint means. The invention is characterised in that the interface means (2) presents at least one user input for effecting a grouped spatialisation command, the command acting on a specified group of audio sources, and the constraint means (3) is programmed to process the group of audio sources as a unitary object for the application of the constraint variables.

The group of audio sources may be identified with a respective group of individually accessible audio tracks.

Preferably, the group of audio sources reflects an internal coherence with respect to the rules for spatialisation.

Suitably, the interface means (2) is adapted to display:

at least one group icon (H) representing a grouped spatialisation command, the icon being positioned according to a topology reflecting a spatialisation and being displaceable by a user, and

links between the icons expressing constraints to be applied between the group icons.

The system may be further adapted to process global commands through the interface means (2) involving a plurality of groups of audio sources simultaneously.

Typically, the global commands comprise at least one among:

a balance between a plurality of groups of audio sources (e.g. between two groups respectively corresponding to acoustic and synthetic components), and

a volume level, whereby positions of groups can be changed simultaneously in a proportional manner.

Preferably, the constraints are one-way constraints, each constraint having a respective set of input and output variables (V) entered by a user through the interface (2).

The system according to the invention may be further adapted to provide a program mode for the recording of mixing constraints entered through the interface means (2) in terms of constraint parameters operative on the groups of audio sources and components of the groups.

Further, the interface means (2) may be adapted to present each the constraint by a corresponding icon such that they can be linked graphically to an object to be constrained through displayed connections.

The constraints may be recorded in terms of metadata associated with the audio stream.

In the above system, each constraint may be configured as a data string containing a variable part and a constraint part.

Further, the variable part may express at least one among:

a variable type, indicating whether it acts on an audio track or the group,

track identification data,

a variable name,

a variable icon,

individual loudness (for track variables),

initial position data (x,y coordinates).

Further yet, the constraint part expresses at least one among:

a constraint type,

constrained variables (identification of individual tracks),

a list of input variables,

a list of output variables,

constraint position,

constraint orientations.

In the above system, multiple audio sources for the spatialisation may be accessed from a common recorded storage medium (optical disk, hard disk).

Further, the constraints may be accessed from the common recorded medium as metadata.

Further yet, the metadata and the tracks in which the audio stream is recorded may be accessed from a common file, e.g. in accordance with the WAV format.

The above system may further comprise an audio data and metadata decoder for accessing from a common file audio data and metadata expressing the constraints and recreating therefrom:

a set of audio streams from each individual track contained in the file, and

the specification of the metadata from an encoded format of the file.

The system may be implemented as an interface to a computer operating system and a sound card.

The inventive system may co-operate with a sound card and three-dimensional audio buffering means, the buffering means being physically located in a memory of the sound card so as to benefit from three-dimensional acceleration features of the card.

The system may further comprise a waitable timer for controlling writing tasks into the buffering means.

In the above system, the input means may be adapted to access audio tracks of the audio stream which are interlaced in a common file.

Further, system may be adapted to co-operate with a three-dimensional sound buffer for introducing an orientation constraint.

Suitably, the constraints comprise functional and/or inequality constraints, wherein cyclic constraints are processed through a propagation algorithm by merely checking conflicts.

The system may further comprise a means for encoding individual sound sources and a database describing the constraints and relating constraint variables into a common audio file through interlacing.

Likewise, the system may further comprise means for decoding the common audio file in synchronism with the encoding means.

Preferably, the system further comprises:

a constraint system module for inputting a database describing the constraints and relating constraint variables for each music title, thereby creating spatialisation commands; and

a spatialisation controller module for inputting the set of audio streams given by encoding means, and spatialisation commands given by the constraint system module.

The system may farther comprise three-dimensional sound buffer means, in which a writing task and a reading task for each sound source are synchronised, the means thereby relaying the audio stream coming from an audio file into a spatialisation controller module and relaying the database describing the constraints and relating constraint variables for each music title into the constraint module means.

Further, the spatialisation controller module may flier comprise a scheduler means for connecting the constraint system module and the spatialisation controller module.

Further still, the spatialisation controller module may comprise static audio secondary buffer means.

The inventive system may further comprise a timer means for waking up the writing task at predetermined intervals.

Typically, the spatialisation controller module is a remote controllable mixing device.

In the above system, the constraint means (3) may be configured to execute a test algorithm.

There is also provided a spatialisation apparatus comprising:

a personal computer having a data reader for reading from a common data medium both audio stream data and data representative of constraints for spatialisation, and

an audio spatialisation system as defined above having its input means adapted to receive data from the data reader.

In the spatialisation apparatus, the computer may comprise a three-dimensional sound buffer for storing contents extracted from data reader.

Further, the sound buffer may be controlled through a dynamic link library (DLL).

The invention also relates to a storage medium containing data specifically adapted for exploitation by an audio spatialisation control system as defined above, comprising a plurality of tracks forming an audio stream and data representative of the processing constraints.

In the above storage medium, the data representative of the processing constraints and the plurality of tracks are recorded in a common file.

Suitably, the data representative of the processing constraints are recorded as metadata with respect to the tracks.

Typically, the tracks are interlaced.

The above storage medium may be in the form of any digital storage medium, such as a CD-ROM, DVD ROM or minidisk.

It may also be in the form of a computer hard disk.

The invention flier concerns a computer program product loadable into the internal memory unit of a general-purpose computer, comprising a software code unit for coding the system as defined above and implementing the means described in the above system, when the computer program product is run on a computer.

The invention is also concerned with a method of controlling an audio spatialisation, comprising the steps of:

accessing an audio stream composed of a plurality of audio sources associated to audio tracks,

receiving and processing constraints expressing rules for a spatialisation of the audio stream, and

entering spatialising commands to the constraint means through an interface. The inventive method is characterised in that

at least one user input is provided for effecting a grouped spatialisation command, the command acting on a specified group of audio sources, and

the group of audio sources is processed as a unitary object for the application of the constraint variables.

The above and the other objects, features and advantages of the present invention will be made apparent from the following description of the preferred embodiments, given as non-limiting examples, with reference to the accompanying drawings, in which:

FIG. 1, already described, is a block diagram showing a music spatialisation system suitable for implementing the present invention;

FIG. 2, already described, is a block diagram showing a sound scene composed of a musical setting and a listener in a spatialisation system implemented in accordance with the prior art;

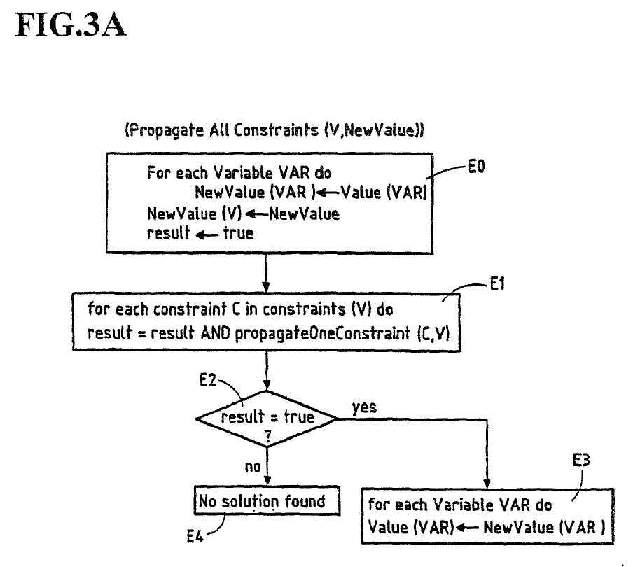

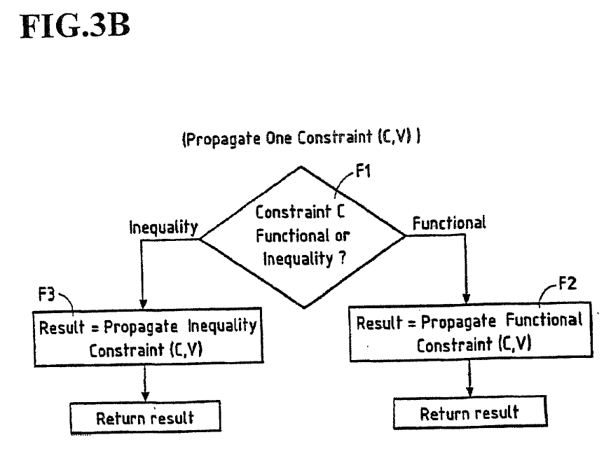

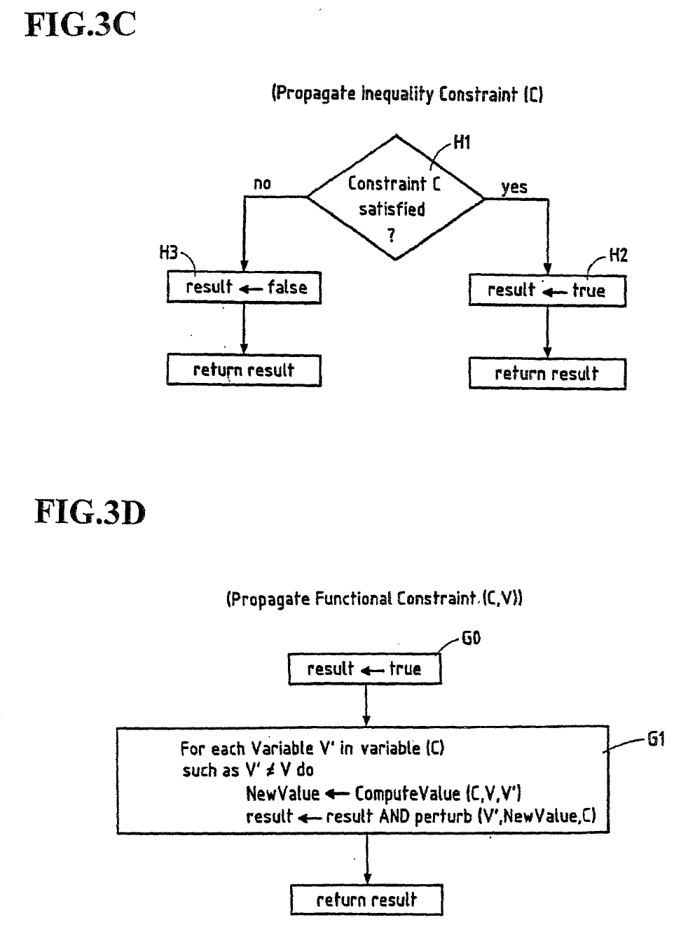

FIGS. 3A to 3E show a constraint propagation algorithm implemented in a known constraint solver;

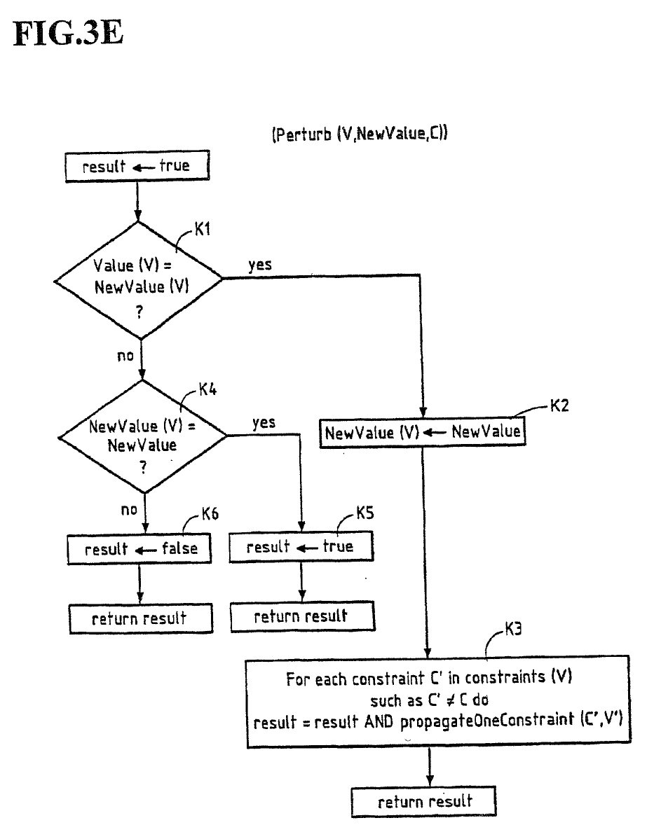

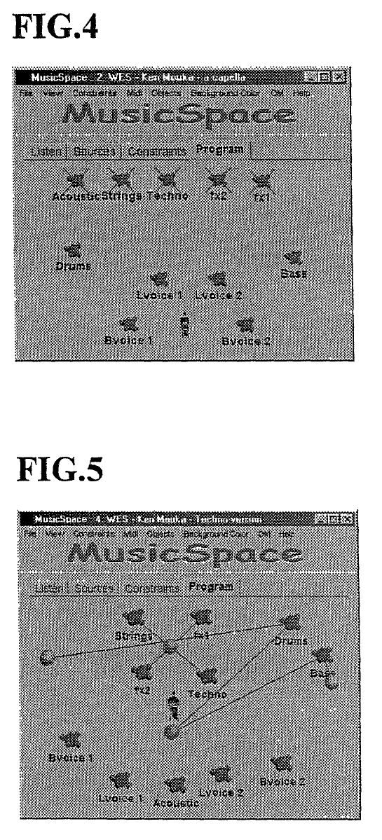

FIG. 4 is a screen displaying an “a capella” rendering of a musical piece;

FIG. 5 is. a screen displaying a techno version with animated constraints;

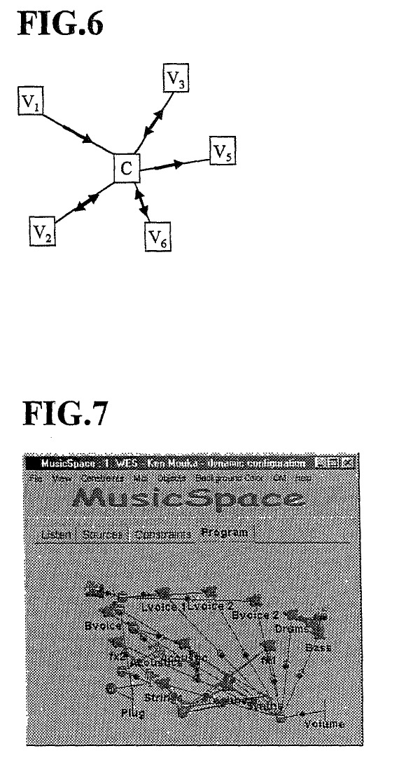

FIG. 6 illustrates a graphic representation of OneWayConstraints Schematic;

FIG. 7 is a screen displaying a dynamic configuration “Program” mode;

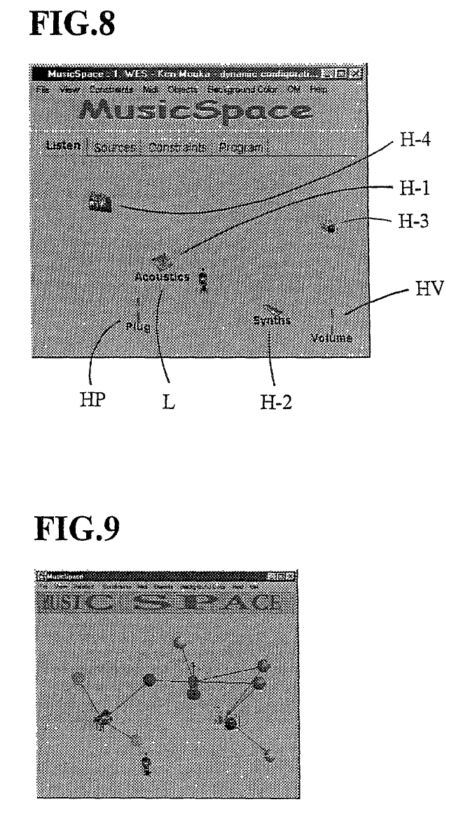

FIG. 8 is a screen displaying a dynamic configuration of the piece “Listen” mode;

FIG. 9 is a screen displaying a MusicSpace interface for setting constraints;

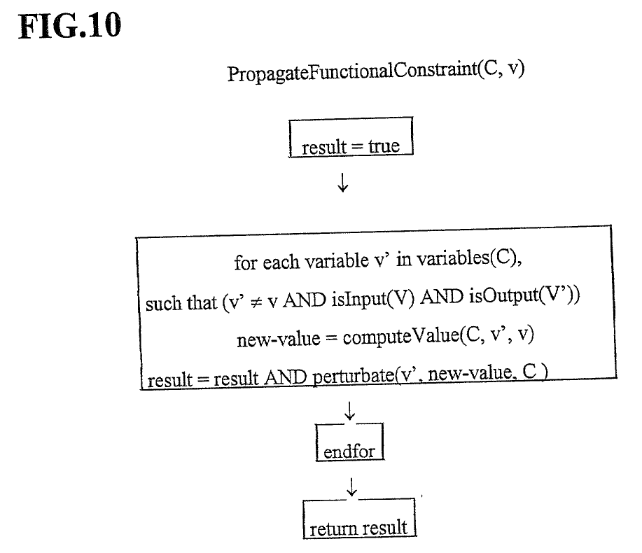

FIG. 10 is a constraint propagation algorithm showing the sequencing of tasks for propagateFunctionalConstraint;

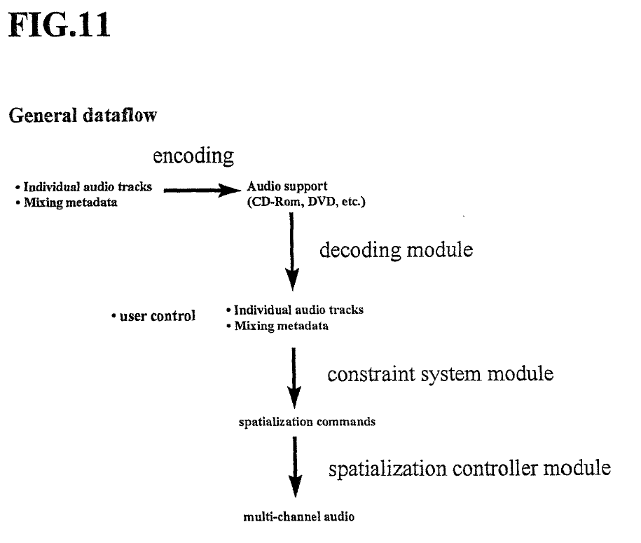

FIG. 11 is a diagram showing the general data flow of the invention;

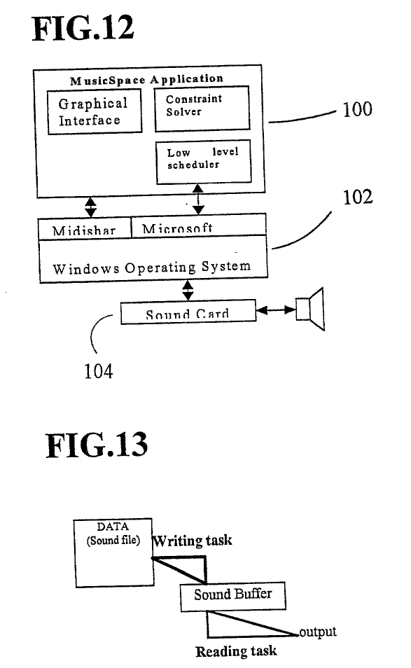

FIG. 12 is a diagram showing a system architecture;

FIG. 13 is a diagram illustrating the steps of synchronizing the writing and reading tasks;

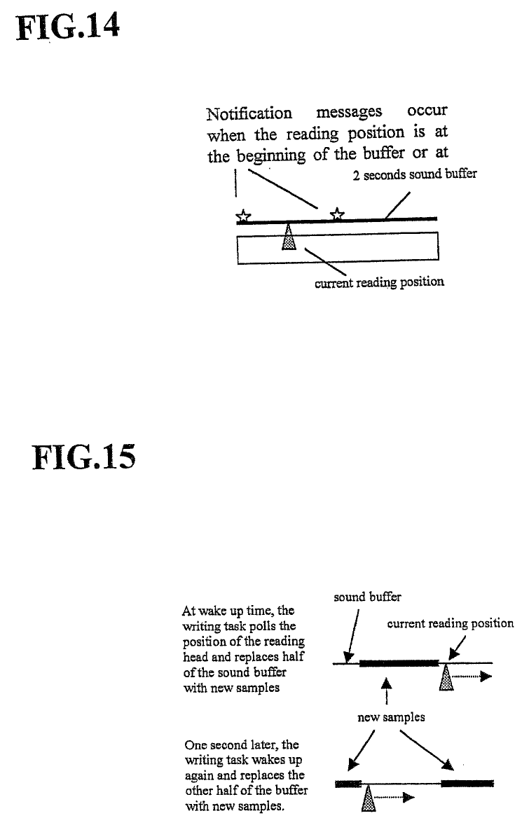

FIG. 14 is a diagram illustrating a streaming model;

FIG. 15 is a diagram illustrating a “timer” model;

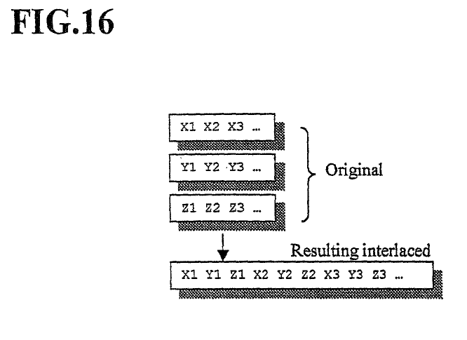

FIG. 16 is a diagram illustrating interlacing three tracks.

The description of the preferred embodiment of the invention will begin with a summary explanation of a system in which it can be implemented, called “MusicSpace”, and will be followed by further description of the basic concepts and means implemented by the present invention.

### The “MusicSpace” system

MusicSpace is an interface for producing high level commands to a spatialiser. Most of the properties of the MusicSpace system concerning its interface and the constraint solver have been disclosed in the works of Pachet, F. and Delerue, O. <<MusicSpace: a Constraint-Based Control System for Music spatialisation >>, in Proceedings of the 1999 International Computer Music Conference, Beijin, China, 1999 and also of Pachet, F. and Delerue, O. <<A Temporal Constraint-Based Music Spatialiser >>, in Proceedings of the 1998 ACM Multimedia Conference, Bristol 1998.

The basic idea in MusicSpace is to represent graphically sound sources in a window, as well as a representation of the listener, for instance as described above with reference to earlier patent application EP-A-0 961 523. In this window, the user may either move his or her representation around, or move the instruments icons. The relative positions of sound sources to the listener's representation determines the overall mixing of the music, according to simple geometrical rules mapping distances to volume and panoramic controls.

The real time mixing of sound sources is then performed by sending appropriate commands from MusicSpace to whatever spatialisation system is connected to it, such as a mixing console, a Midi Spatialiser, or a more sophisticated spatialisation system such as the one described by Jot and Warusfel supra.

FIGS. 3A to 3E are flow charts showing how the constraint algorithm is implemented in accordance with EP-A-0 961 523 to achieve such effects. More specifically:

FIG. 3A shows a procedure called “propogateAllConstraints” and having as parameters a variable V and a value NewValue;

FIG. 3B shows a procedure called “propapagateOneConstraint” and having as parameters a constraint C and a variable V;

FIG. 3C shows a procedure called “propagateInequality/Constraint” and having as parameters a constraint C;

FIG. 3D shows a procedure called “propagateFunctionalConstraint” and having as parameters a constraint C and a variable V; and

FIG. 3E shows a procedure called “perturb” and having as parameters a variable V, a value NewValue and a constraint C.

The procedure “propagateAllConstraints” shown in FIG. 3A constitutes the main procedure of the algorithm. The main variable V contained in the set of parameters of this procedure corresponds to the position, in the referential (O,x,y), of the element (the listener or sound source) that has been moved by the user. The value NewValue, also contained in the set of parameters of the procedure, corresponds to the value of this position once it has been modified by a user. At an initial step E0, the various local variables used in the procedure are initialised. At a following step E1, the procedure “propagateOneConstraint” is called for each constraint C in the set of constraints involving the variable V. If, at a step E2, a solution has been found to the constraints-based problem in such a way that all constraints activated by the user can be satisfied, the new positions of the sound sources and the listener replaces the corresponding original positions in the constraint solver 3 and are transmitted to the interface 2 and the command generator 4 (cf. FIG. 1) at a step E3. If, on the contrary, no solution has been found at the step E2, the element moved by the user is returned to its original position, the positions of the other elements are maintained unchanged, and a message “no solution found” is displayed on the display 20 at step E4.

In the procedure “propagageOneConstraint” shown in FIG. 3B, it is determined at step F1 whether a constraint C is a functional constraint or an inequality constraint. If the constraint C is a functional constraint, the procedure “propagateFunctionalConstraint” is called at step F2. If the constraint C is an inequality constraint, the procedure “propagateInequalityConstraint” is called at a step F3.

In the procedure “propagateInequalityConstraint” shown in FIG. 3C, the constraint solver 3 merely checks at step H1 whether the inequality constraint C is satisfied. If the inequality constraint C is satisfied, the algorithm continues at a step H2. Otherwise, a Boolean variable “result” is set to FALSE at step H3 in order to make the algorithm stop at the step E4 shown in FIG. 3A.

In the procedure “PropagateFunctionalConstraint” shown in FIG. 3D, after the initialisation step G0, a step G1 is performed, wherein for each variable V′ in the set of variables involved by the constraint C such as V′ is different from V:

a procedure called “ComputeValue” having as parameters the constraint C and the variables V and v′ is called; and

the procedure “perturb” is called based on a value “NewValue” calculated by the procedure “ComputeValue”.

The role of the procedure “ComputeValue” is to give the variable V′ an arbitrary value depending on the new value of the variable V and the constraint C, which is here a functional constraint. For simplification purposes, this procedure shall be described first in the general context of a constraint involving three given variables designated X, Y and Z respectively. An example of a functional constraint linking the variables X, Y and Z is:

X+Y+Z=Constant.

If X is the variable whose value is modified by the user, the constraint solver 3 will have to modify the values of the variables Y and Z in order for the constraint to be satisfied. For a given value of X, there are an infinite number of solutions for the variables Y and Z. Arbitrary value changes are applied respectively to the variables Y and Z as a function of the value change imposed by the user to the variable X, thereby determining one solution. For instance, if the value of the variable X is increased by a value δ, it can be decided to decrease the respective values of the variables Y and Z each by the value δ/2.

Such arbitrary value changes are carried out for non-binary constraints, i.e. constraints that involve more than two variables. In the case of a binary constraint, such as X=Y=Constant, the value of the variable other than that perturbed by the user can be determined directly as follows:

Y=Constant −X.

The procedure “ComputeValue” shall be described in the case of constraints relating to the positions of the sound sources, namely related-objects constraint and anti-related objects constraint.

When the constraint is the related-objects constraint, the procedure “ComputeValue” consists of calculating the following ratio:

ratio=∥NewValue (V)−S₀∥/∥Value(V)−S₀∥,

where NewValue (V) denotes the new value of the perturbed variable V, value (V) the original of the variable V, and S₀ the position of the listener. This ratio corresponds to the current distance between the source represented by the variable V and the listener divided by the original distance between the sound source represented by the variable V and the listener.

The value “NewValue” which is assigned to the variable V′ is then calculated as follows:

NewValue=(Value(V′)−S₀)×ratio+S₀,

where Value (V′) denotes the original value of the variable V′.

Thus, in response to a change in the value of the variable V, the value of the variable V′ linked to the variable V by the related-objects constraints is changed in such a manner that the distance between the sound source represented by the variable V′ and the listener is changed by the same ratio as that associated with the variable V.

When the constraint is the anti-related objects constraint, the procedure “ComputeValue” consists of:

calculating a ratio, which is the same ratio as described above, namely:

ratio=∥NewValue (V)−S₀∥/∥Value (V)−S₀∥,

and

calculating the new value for the variable V′ as follows:

NewValue=(Value (V′)−S₀)×ratio^{1/(Nc-1)}+S₀,

where Nc is the number of variables involved by the constraint C.

Thus, in response to a change in the value of variable V, each variable V′ linked to the variable V by the anti-related objects constraint is given an arbitrary value in such a way that the product of the distances between the sound sources and the listener remains constant.

At step G1 of the procedure, “propagateFunctionalConstraint”, after a new value for a given variable V′ is arbitrarily set by the procedure “ComputeValue” as explained above, the procedure “perturb” is performed. The procedure “perturb”′ generally consists in propagating the perturbation from the variable V′ to all the variables which are linked to the variable V′ through constraints C′ that are different from the constraint C′.

At the heart of this algorithm is the procedure propagate (Sᵢ, NewValue), where Sᵢ is the originally modified sound source and NewValue is the value proposed by the user.

The invention provides a development of this earlier spatialisation system according to a which high level command language is now use for moving groups of related sound sources, rather than individual sound sources. These new high level commands may be used to control arbitrary spatialisation systems.

Because the design of the basic MusicSpace system is now established in the art, only the technical issues concerning the audio version shall be described in the context of the invention.

The system presented here has two main modules: 1) a control system, which generates high level spatialisation commands, and 2) a spatialisation module, which carries out the real time spatialisation and mixing of audio sources. The control system is implemented using the Midishare operating system (see Fober, D., Letz, S. and Orlarey, Y. <<Midishare joins the Open Source Softwares >>), in Proceedings of the 1999 International Computer Music Conference) and a Java-based constraint solver and interface. The spatialisation module is an interface to the underlying operating system (see, for example, Microsoft DirectX; online information http://msdn.microsoft.com/directx/ (home site of the API, download and documentation) and http://www.directx.coin/ for programming issues) and the sound card.

MusicSpace also has applications outside the field of spatialisation, being useable for any situation where:

a) Streams of real time data can be controlled by discrete parameters (e.g. streams of audio sources controlled by distance, pan, directivity, etc.), and/or

b) Relations between these parameters can be expressed as constraints or combinations of constraints.

Such situations occur frequently in music composition, sound synthesis, and real time control. Other applications concern the automatic animation of sound sources (e.g. defining sources which revolve automatically around other sources, or which move through a path itself defined with constraints).

Information on MusicSpace and related topics can be obtained at http://www.csl.sony.fr/MusicSpace.

### Dynamic Mixing

The listening experience may be highly improved by postponing the mixing process to the latest possible time in the music listening chain. Instead of delivering the music in the traditional ready-to-use mixed form, designed for an imposed reproduction set-up (stereo, Dolby DTS, . . . ), the key idea of dynamic mixing is to deliver independent musical tracks that are mixed or spatialised altogether at the time of listening, and according to a given diffusion set-up.

To do so, a set of instructions is attached to the audio tracks, describing how the musical tracks should be mixed and what are the important relations to be maintained between the sound sources. Thus, beyond its adaptability to the diffusion system, “on-the-fly” mixing also brings more freedom to listeners: since several such mixing descriptions can be provided for a single music piece, the listener can choose between several renderings of the piece to emphasise specific musical dimensions, or to fit with his or her particular taste.

### Musical Rendering

Having access to the individual tracks of a given music title, the present invention allows to create several arrangements of the same set of sound sources, which are presented to the user as handles. The first possibility is of course to recreate the original mixing of the standard distributed CD version. It is also possible to define alternative configurations of sound sources, as described below.

FIG. 4 shows an “a capella” rendering example of a music title. To achieve the a capella style, all the instruments yielding some harmonic content are muted (cross overlain on the. corresponding icons). The various voice tracks (lead singer, backing vocals) are kept and located close to the listener. To avoid a dry mix, some drums and bass are also included, but located a bit farther from the listener. Note that in accordance with the invention, the interface shows not individual musical instruments, but rather group of instruments identified collectively by a corresponding icon or “handle”, designated generically by figure reference H: acoustic, strings, bass, drums (each percussion source is in this case amalgamated into a single set), . . .

Several other renderings can be created using this same set of sound sources, such as an “unplugged” version or animated mix, as described below.

FIG. 5 displays a “techno” rendering of the same music title, obtained activating the techno handle: here, emphasis is placed on the synthetic and rhythmic instruments that are located to the front in the auditory scene. To maintain consistency in the result, the voice tracks and the acoustic instruments are preserved and located in the back, so that they do not draw all the listener's attention.

Animated constraints are used for this rendering, so as to bring a variety to the resulting mix. The groups handles for strings, sound effects and techno tracks are related together by a rotating constraint, so that emphasis is put periodically on each of them as they come closer to the listener. Drums and bass tracks are also related with a rotating constraint, but some angle limit constraints force their movement to oscillate alternatively between left and right sides.

While the algorithm of patent application EP-A-0 961 523 considers all variables are implicitly considered both as input and output, the invention allows to specify, for one constraint, exactly which variables will be input is and/or output. This approach is symbolised in FIG. 6. Each constraint C is endowed with a list of so-called “input variables”, and a list of “output variables” V. In the illustrated example, the input variables are: V1, V2, V3, V6; and output variables are: V2, V3, V5,V6.

The specification of these two lists is done by the user, through the graphical interface, as shown in FIG. 7. Here, the interface display shows the relevant links between groups according to the programmed constraints. The links can be inserted, displaced or removed through suitable input commands on the interface.

This enables a grouping of sound sources in accordance with specific constraints. A thus-grouped set of sound sources will then form a coherent whole to which the constraints solving algorithm can applied with allowable solutions. At the level of the user interface, what is displayed is not the individual sound sources, but rather the above-mentioned groups of sound sources (e.g. acoustics, strings, voice, . . . ). The user is then no longer presented with potentially conflicting spatialisation possibilities resulting from 5 each sound source being considered individually as a variable input. Rather, in accordance with the invention, the user can displace one or a number of presented groups of sound sources-through collective commands. The internal consistency of the group can then ensure that the entered displacement command shall more likely find acceptable solutions with the constraint solver 3 (FIG. 1).

### High Level Handles

A user “handle” in accordance with the present invention encapsulates a group of sound sources and their related constraints into a single interface object. These handles are implemented by so-called “one way constraints”, which are a lightweight extension of the basic constraint solver. Thanks to these handles, the user may easily change the overall mixing dynamically.

Several handles may coexist in a given configuration, providing the user a set of coherent alternatives to the traditionally imposed unique mixing.

In an example shown on FIG. 8, the sound sources are no longer shown: rather, the user has access to just a set of proposed handles H that are created specially for the music title. In this example, the user disposes of a first handle H-1 to adjust the acoustic part of the sound sources, a second handle H-2 to adjust the synthetic instruments, a third handle H-3 for the drums and a fourth handle H-4 for the voices. There is also provided a handle, referred to as a “plug” handle HP, which allows a balance control between the acoustic and the synthetic parts: bringing the “plug” handle HP closer to the listener L will enhance the synthetic part and give less importance to acoustic instruments, and vice versa. Similarly, a “volume” handle HV is provided to change the position of all sound sources simultaneously in a proportional manner.

The example shown in FIG. 8 makes extensive use of the constraint system to build the connections between the sound sources (such as represented on FIG. 4) and the corresponding handles H.

FIG. 7 displays the interface of the present system when it is in “program” mode. In this mode all the elements for the spatialisation are represented: handles H, sound sources, constraints and one way constraints.

### Constraints and Mixing Consistency

The problem with allowing users to change the configuration of sound sources—and hence, the mixing—is that they do not have the knowledge required to produce coherent, pleasant-sounding mixings. Indeed, the knowledge of the sound engineer is difficult to explicit and to represent. Its basic actions are exerted on controls such as faders and knobs. However, mixing also involves higher level actions that can be defined as compositions of irreducible actions. For instance, sound engineers may want to ensure that the overall energy level of the recording always lies between reasonable boundaries. Conversely, several sound sources may be logically dependent on one another. For instance, the rhythm section may consist in the bass track, the guitar track and the drum track.

Another typical mixing action is to assign boundaries to instruments or groups of instruments so that they always remain within a given spatial range. The consequence of these actions is that sound levels are not set independently of one another. Typically, when a fader is raised, another one (or a group of other faders) will be lowered.

This type of knowledge of sound spatialisation is encoded as a set of constraints, which are interpreted in real time by an efficient constraint propagation algorithm integrated into the MusicSpace. Constraints are relations that should always be satisfied. Constraints are stated declaratively by the designer, thereby obviating the need to program complex algorithms. Constraint propagation algorithms are particularly relevant for building reactive systems typically for layout management of graphical interfaces, as disclosed by Hower W., Graf W. H., in an article entitled “a Bibliographical Survey of Constraint-Based Approaches to CAD, Graphics, Layout, Visualization, and related topics”, Knowledge-Based Systems, Elsevier, vol. 9, n. 7, pp. 449-464, 1996.

A set of constraints, appropriate for specifying “interesting” relations between sound sources have already been discussed in application EP-A-0 961 523. In particular, this reference discusses the following constraints:

related-objects constraints expressible by inequality ∥pi−1∥αij ∥pj−1∥, where pi and pj are the positions of the two different sound sources and αij are predetermined constants,

anti-related (anti-link) objects constraints which specify that the product of the distances between the sound sources involved by the constraint and the listener should remain constant, i.e. the product for i=1 to n of ∥pi−1∥=constant,

radical limit constraints, which specify a distance value from the listener that the sound sources involved by the constraint should never cross, i.e. for each source ∥pi−1∥≧αinf−1, where αinf−1 designates a limit lower imposed for the sound source having the position pi and/or ∥pi−1∥≦αsup−1, where αsup−1 designates an upper limit imposed for the sound source having the position pi, and

angular constraints, which specify that the sound sources involved in the constraint should not cross an angular limit with respect to the listener.

Most of the constraints on mixing involve a collection of sound sources and the listener. The most useful ones in the context of the present invention are described hereafter.

Constant Energy Level

This constraint states that the energy level between several sound sources should be kept constant. Intuitively, it means that when one source is moved toward the listener, the other sources should be “pushed away”, and vice-versa.

Constant Angular Offset

This constraint is the angular equivalent of the preceding one. It expresses that the spatial configuration of sound sources should be preserved, i.e. that the angle between two objects and the listener should remain constant.

Constant Distance Ratio

The constraint states that two or more objects should remain in a constant distance ratio to the listener:

Radial Limits of Sound Sources

This constraint allows to impose radial limits in the possible regions of sound sources. These limits are defined by circles whose center is the listener's representation.

Grouping Constraint

This constraint states that a set of n sound sources should remain grouped, i.e. that the distances between the objects should remain constant (independently of the listener's representation position).

Other typical constraints include symbolic constraints, holding on non geographical variables. For instance, an “Incompatibility constraint” imposes that only one source should be audible at a time: the closest source only is heard, the others are muted. Another complex constraint is the “Equalising constraint”, which, imposes that the frequency ratio of the overall mixing should remain within the range of an equaliser. For instance, the global frequency spectrum of the sound should be flat.

### Constraint Algorithm

The examples of constraints given above show that the constraints have the following properties:

the constraints are not linear. For instance, the constant energy level (between two or more sources) is not linear,

the constraints are not all functional. For instance, geometrical limits of sound sources are typically inequality constraints,

the constraints induce cycles. For instance, a simple configuration with two sources linked by a constant energy level constraint and a constant angular offset constraint already yields a cyclic constraint graph.

In the preferred embodiment, the constraint algorithm is based on a simple propagation scheme, and allows to handle functional constraints and inequality constraints. It handles cycles simply by checking conflicts. An important property of the algorithm is that new constraint classes may be added easily, by defining the set of propagation procedures (see Pachet and Delerue, 1998, supra).

### Extension of the Constraint System

In accordance with the invention, there are also included new constrained variables identified to the above-mentioned “handles” H. These objects are constrained variables which are not assigned to a particular audio track.

The embodiment of the invention also extends the constraint propagation mechanism to include the management of so-called “one-way constraints”. This extension of the constraint solver consists in propagating the perturbation in a constraint “only” in the directions allowed by the constraint.

1) Handle Variables

From the view point of implementation, each handle is considered exactly as a sound source variable, with the following restriction:

The positions of handle variables are not considered by the command generator 4 (of FIG. 1). The link between the constraint solver 3 and the command generator 4 is therefore not systematic, and a test is introduced to check that the variable is indeed related to an actual sound source.

FIG. 7 is a graph showing OneWayConstraints. The small arrows represent the information of which variables are “input”, and which are “output”, depending on the orientation of the arrow.

2) Extension of the Algorithm in Accordance with the Invention

### Interface

The interface for setting constraints may be straightforward: each constraint is represented by a button, and constraints are set by first selecting the graphical objects to be constrained, and then clicking on the appropriate constraint. Constraints themselves are represented by a small ball linked to the constrained objects by lines.

FIG. 9 displays a typical configuration of sound source for a Jazz trio. The following constraints have been set:

the bass and drum sound sources are linked by a “constant distance ratio” constraint, which ensures that they remain grouped, distance wise,

the piano is linked with the rhythm section by a “balance” constraint. This ensures that the total level between the piano and the rhythms section is constant,

the piano is limited in its movement by a “distance max” constraint. This ensures that the piano is always heard.

the drum is forced to remain in an angular area by two “angle constraints”. This ensures that the drum is always more or less in the middle of the panoramic range.

Starting from the initial situation of FIG. 9, the user moves the piano closer to his representation. The constraint system is then triggered, and the is other sound sources are moved to satisfy the constraint set.

### Database

1) Specification of The Metadata Format

Particulars for the “constraint” used in the present invention are summarized hereafter.

Each configuration of constraint set is represented by a string as follows:

The format contains two parts:

the “variable part”

the “constraint part”

i) Variable part

Each individual sound track is given a number from 1 to n. Each track parameter is specified, one by one, in the following order:

variable type (“handle” or “track”)

variable name,

variable icon,

individual loudness (only for “track” variables)

initial position (x, y coordinates)

ii) Constraint part

Each constraint is represented by the following information:

constraint type (one of the possible constraint types),

list of input variables

list of output variables

constraint position

2) Processing Characteristics

In comparison with the prior art, the embodiment features the following characteristics

i) encoding multiple audio sources into a data medium (e.g. CD-ROM, or DVD-ROM) and decoding therefrom: therefore explicit handling of audio sources, compared to the technique used in EP-A-0 961 523 which focuses on the Midi format.

ii) introduction of high level control, on top of the audio source level. These controls encapsulate sets of sound sources, and allow the user to have more sophisticated control on the configuration of sound sources.

iii) a further addition to the algorithm, which consists in adding a test in the procedure “propagateFunctionalConstraint”, as shown in FIG. 10.

In the embodiment of the present invention, the new test is incorporated into the above procedure.

FIG. 11 is a diagrammatic representation of the general data flow of an example according to the invention.

At an initial stage, two types of data are entered for encoding: the individual audio tracks of a given musical title, and mixing metadata which specifies the basic mixing rules for these tracks. The encoded form of these two types of data is recorded in a common file on an audio support used in consumer electronics, such as a CD-ROM, DVD, minidisk, or a computer shared disk. The audio support can be provided by a distributor for use as music recording specially prepared for the present spatialisation system.

For playing the music recorded in this manner, the audio support is placed in a decoding module of the spatialisation system, in which the two types of data mentioned above are accessed for providing a user control through the interface. The data is then processed by the constraint system module to yield spatialisation commands. These are entered to a spatialisation controller module which delivers the correspondingly spatialised multi-channel audio for playback through a sound reproduction system.

3) Specification of Modules

i) Audio and metadata encoder

This modules takes as input:

a set of individual audio tracks (monophonic format, all other parameters can be accommodated by the invention, e.g. sampling rate, resolution, etc.,)

a set of metadata, describing the constraints and related constrained variables needed for the constraint system. These metadata are represented in a symbolic, textual format and

a format name

The format name supports multiplexed audio data and arbitrary metadata, such as AIFFP, WAV, or Mpeg4 (not exclusive).

According to the format name, the module encodes the audio tracks and the metadata into a single file. The format of this file is typically WAV. The encoding of several monophonic tracks into a single WAV file is considered here as standard practice. The metadata information is considered as a user specific information and is represented in the WAV format as an <assoc-data-list>. For further information, reference can be made e.g. to the specification of the WAV format (htt://www.cwi.nl/ftp/audio/RIFF-format; or http://vision1.cs.umr.edu/˜johns/links/music/audiofile1.html).

Other similar formats (e.g. AIFF, or formats of the Mpeg family) can be handled in the same way, i.e. by using fields designed for user specific information.

The specification of the format of the metadata is given hereinafter.

ii) Audio and metadata decoder.

This module takes as input a file in one of the formats created by the encoder. It recreates:

a) a set of audio streams from each individual track, and

b) the specification of the metadata from the encoded format.

The set of audio streams is given as input to the spatialisation module.

The set of metadata is given as input to the constraint system module.

The actual decoding from the single file to the set of tracks and metadata is done using a conventional decoder, for instance a WAV decoder (similarly, this is considered here as standard practice).

### 3D-Sound Buffer Technology

Although DirectX may arguably not be the most accurate spatialisation system around, this extension has a number of benefits for the implementation of the invention.

First, DirectX provides parameters for describing 3D sound sources which can be constrained using MusicSpace. For instance, a DirectX sound source is endowed with an orientation, a directivity and even a Doppler parameter. An “orientation” constraint has been designed and included in the constraint library of MusicSpace. This constraint states that two sound sources should always “face” each other: when one source is moved, the orientation of the two sources moves accordingly. Second, DirectX allows to handle a considerable number of sound sources in real time. This is useful for mixing complex symphonic music, which have often dozens of related sound sources. Lastly, the presence of DirectX on a number of PCs makes MusicSpace easily useable to a wide audience.

The spatialisation controller module takes as input the following information:

the set of individual audio streams as decoded by the decoder module, and

spatialisation commands given by the constraint system.

This module is identical to the module described in EP-A-0 961 523, except that it is redesigned specifically for reusing the DirectX spatialisation middleware of Microsoft (registered trademark).

The audio version is implemented by a specific Dynamic Link Library (dll) for PCs which allows MusicSpace to control Microsoft DirectX 3D sound buffers. This dll of MusicSpace-audio basically provides a connection between any Java application and DirectX, by converting DirectX's API C++ types into simple types (such as integers) that can be handled by Java.

As shown by the system architecture of FIG. 12, the spatialisation module 100 is an interface to the underlying operating system (Microsoft DirectX supra) 102 and the sound card 104. This module 100 takes in charge the real time streaming of audio files as well as the conversion of data types between java (interface) and C++ (spatialisation module). As illustrated in FIG. 12, a connection to the spatialisation system is embodied by implementing a low level scheduler which manages the various buffers of the sound card 104. The system shown in FIG. 12 runs on a personal computer platform running Windows 98. Experiments were driven on a multimedia personal computer, equipped with a Creative Sound Blaster Live sound card 104 and outputting to a quadraphonic speaker system: up to 20 individual monophonic sound files can be successfully spatialised in real-time.

1) Synchronization

Dynamix mixing yields a synchronization issue between the two tasks that write and read from/to the 3D-sound buffer. The reading task is handled by the spatialisation system (i.e. DirectX) and our application needs to fill ‘in-time’ this buffer with the necessary samples.

As mentioned supra, FIGS. 13, 14 and 15 illustrate the steps of synchronizing the writing and reading tasks.

To achieve a correct synchronization between the audio streaming task (reading the sound files) and the audio output, the standard technique consists in using notification events on the position of the reading head in the buffer. In this implementation, the reading task notifies the writing task when the reading position has gone over a certain point.

The sound buffer is thus split into two halves and when a notification event is received, the writing task clears and replaces samples for the half of the buffer that is not currently being read.

However, to access these notification events, the buffers have to be handled by the operating system. As a result, they cannot benefit from the hardware acceleration features and for instance use the quadraphonic output of the sound card.

The solution chosen consists in creating “static” 3D audio secondary buffers in DirectX. These buffers are physically located in the sound card memory and thus can take advantage of its 3D acceleration features. Since in this case the notification events are no longer available, they are replaced by a “waitable timer” that wakes up the writing task every second. The writing task then polls the reading task to get its current position and updates the samples already read. Since this timer was introduced only in the Windows version 98 and NT4, the system cannot be used under Windows 95 in that form.

In the “timer” model shown in FIGS. 15 and 16, each buffer requires 2 seconds of memory within the sound card: this represents less than 200 kbytes for a 16-bit mono sample recorded at a 44100 Hz sample frequency. Actual sound cards internal memory can contain up to 32 megabytes, so the number of tracks the system can process in real time is not limited by memory issues.

2) Access Timing

One important issue in the audio version implementing the present invention concerns data access timing, i.e. to the audio files to be spatalised. The current performance of hard disks allow to read a large number of audio tracks independently. A typical music example lasts three and a half minutes and is composed of about 10 independent mono tracks: the required space for such a title is more than 200 megabytes.

External supports such as CD-ROM are not as flexible as hard-disks: reading independently a large number of tracks from a CD-ROM is currently not possible. Nevertheless, this problem can be solved by interlacing the different audio tracks in a single file, as shown in FIG. 16: the reading head does not have to jump continuously from one position to another to deliver the samples for each track, and the samples are read continuously. The WAV format supports multi-track interlaced files.

Each track has to be read: muting a track will not release any CPU resource. The synchronization between each track has to be fixed once for all, whereupon one track cannot by offset with respect to another. Each track is read at the same speed or sample rate. This excludes the possibility of using the DirectX Doppler effect, for instance, which is implemented by shifting slightly the reading speed of a sound file according to the speed and direction of the source with respect to the listener.

These considerations apply in specific and experimental applications, and do not block the goals of the invention: the number of tracks for a music title can be fixed in advance and there is no reason to modify the offset between the tracks.

1. System for controlling an audio spatialisation in real time, comprising:
input means (50) for accessing an audio stream composed of a plurality of audio sources associated to audio tracks,
constraint means (3) for receiving and processing constraints expressing rules for a spatialisation of said audio stream, and
interface means (2) for entering spatialising commands to said constraint means,
characterised in that said interface means (2) presents at least one user input for effecting a grouped spatialisation command, said command acting on a specified group of audio sources, and
said constraint means (3) is programmed to process said group of audio sources as a unitary object for the application of said constraint variables.

2. System according to claim 1, wherein said group of audio sources is identified with a respective group of individually accessible audio tracks.

3. System according to claim 1 or 2, wherein said group of audio sources reflects an internal coherence with respect to said rules for spatialisation.

4. System according to any one of claims 1 to 3, wherein said interface means (2) is adapted to display:
at least one group icon (E) representing a grouped spatialisation command, said icon being positioned according to a topology reflecting a spatialisation and being displaceable by a user, and
links between said icons expressing constraints to be applied between said group icons.

5. System according to any one of claims 1 to 4, further adapted to process global commands through said interface means (2) involving a plurality of groups of audio sources simultaneously.

6. System according to claim 5, wherein said global commands comprise at least one among:
a balance between a plurality of groups of audio sources (e.g. between two groups respectively corresponding to acoustic and synthetic components), and
a volume level, whereby positions of groups can be changed simultaneously in a proportional manner.

7. System according to any one of claims 1 to 6, wherein said constraints are one-way constraints, each constraint having a respective set of input and output variables (V) entered by a user through said interface (2).

8. System according to any one of claims 1 to 7, further adapted to provide a program mode for the recording of mixing constraints entered through said interface means (2) in terms of constraint parameters operative on said groups of audio sources and components of said groups.

9. System according to claim 8, wherein said interface means (2) is adapted to present each said constraint by a corresponding icon such that they can be linked graphically to an object to be constrained through displayed connections.

10. System according to any one of claims 1 to 9, wherein said constraints are recorded in terms of metadata associated with said audio stream.

11. System according to any one of claims 1 to 10, wherein each constraint is configured as a data string containing a variable part and a constraint part.

12. System according to claim 11, wherein said variable part expresses at least one among:
a variable type, indicating whether it acts on an audio track or said group,
track identification data,
a variable name,
a variable icon,
individual loudness (for track variables),
initial position data (x,y coordinates).

13. System according to claim 11 or 12, wherein said constraint part expresses at least one among:
a constraint type,
constrained variables (identification of individual tracks),
a list of input variables,
a list of output variables,
constraint position,
constraint orientations.

14. System according to ally one of claims 1 to 13, wherein multiple audio sources for said spatialisation are accessed from a common recorded storage medium (optical disk, hard disk).

15. System according to claim 14, wherein said constraints are accessed from said common recorded medium as metadata.

16. System according to claim 15, wherein said metadata and said tracks in which said audio stream is recorded are accessed from a common file, e.g. in accordance with the WAV format.

17. System according to any one of claims 1 to 16, further comprising an audio data and metadata decoder for accessing from a common file audio data and metadata expressing said constraints and recreating therefrom:
a set of audio streams from each individual track contained in said file, and
the specification of said metadata from an encoded format of said file.

18. System according to any one of claims 1 to 17, implemented as an interface to a computer operating system and a sound card.

19. System according to any one of claims 1 to 18, cooperating with a sound card and three-dimensional audio buffering means, said buffering means being physically located in a memory of said sound card so as to benefit from three-dimensional acceleration features of said card.

20. System according to claim 19, further comprising a waitable timer for controlling writing tasks into said buffering means.

21. System according to any one of claims of 1 to 20, wherein said input means is adapted to access audio tracks of said audio stream which are interlaced in a common file.

22. System according to any one of claims 1 to 21, adapted to cooperate with a three-dimensional sound buffer for introducing an orientation constraint.

23. System according to any one of claims 1 to 22, wherein said constraints comprise functional and/or inequality constraints, wherein cyclic constraints are processed through a propagation algorithm by merely checking conflicts.

24. System according to any one of claim 1 to 23, further comprising a means for encoding individual sound sources and a database describing the constraints and relating constraint variables into a common audio file through interlacing.

25. System according to claim 24, further comprising means for decoding said common audio file in synchronism with said encoding means.

26. System according to any one of claim 1 to 25, further comprising:
a constraint system module for inputting a database describing the constraints and relating constraint variables for each music title, thereby creating spatialisation commands; and
a spatialisation controller module for inputting said set of audio streams given by encoding means, and spatialisation commands given by said constraint system module.

27. System according to claim 26, further comprising three-dimensional sound buffer means, in which a writing task and a reading task for each sound source are synchronised, said means thereby relaying said audio stream coming from an audio file into a spatialisation controller module and relaying said database describing the constraints and relating constraint variables for each music title into said constraint module means.

28. System according to claim 26 or 27, wherein said spatialisation controller module further comprises a scheduler means for connecting said constraint system module and said spatialisation controller module.

29. System according to any one of claims 27 to 28, wherein said spatialisation controller module comprises static audio secondary buffer means.

30. System according to any one of claims 27 to 29, further comprising a timer means for waking up said writing task at predetermined intervals.

31. System according to any one of claims 26 to 30, wherein said spatialisation controller module is a remote controllable mixing device.

32. System according to any one of claims 1 to 31, wherein said constraint means (3) is configured to execute a test algorithm.

33. A spatialisation apparatus comprising:
a personal computer having a data reader for reading from a common data medium both audio stream data and data representative of constraints for spatialisation, and
an audio spatialisation system according to any one of claims 1 to 32 having its input means adapted to receive data from said data reader.

34. Spatialisation apparatus according to claim 33, wherein said computer comprises a three-dimensional sound buffer for storing contents extracted from data reader.

35. Spatialisation apparatus according to claim 34, wherein said sound buffer is controlled through a dynamic link library (DLL).

36. A storage medium containing data specifically adapted for exploitation by an audio spatialisation control system according to any one of claims 1 to 32, comprising a plurality of tracks forming an audio stream and data representative of said processing constraints.

37. Storage medium according to claim 36, wherein said data representative of said processing constraints and said plurality of tracks are recorded in a common file.

38. Storage medium according claim 36 or 37, wherein said data representative of said processing constraints are recorded as metadata with respect to said tracks.

39. Storage medium according to any one of claims 36 to 38, wherein said tracks are interlaced.

40. Storage medium according to any one of claims 35 to 39 in the form of any digital storage medium, such as a CD-ROM, DVD ROM or minidisk.

41. Storage medium according to any one of claims 36 to 40 in the form of a computer hard disk.

42. A computer program product loadable into the internal memory unit of a general-purpose computer, comprising a software code unit for coding the system according to any one of claims 1 to 32 and implementing the means described in said system, when said computer program product is run on a computer.

43. A method of controlling an audio spatialisation, comprising the steps of:
accessing an audio stream composed of a plurality of audio sources associated to audio tracks,
receiving and processing constraints expressing rules for a spatialisation of said audio stream, and
entering spatialising commands to said constraint means through an interface,
characterised in that at least one user input is provided for effecting a grouped spatialisation command, said command acting on a specified group of audio sources, and
said group of audio sources is processed as a unitary object for the application of said constraint variables.
